(19) United States
(12) Patent Application Publication
(10) Pub. No.: US 2011/0244610 A1
(43) Pub. Date: Oct. 6, 2011

(54) METHOD FOR PRODUCING GROUP III NITRIDE SEMICONDUCTOR LIGHT-EMITTING DEVICE

(75) Inventors: Yoshiki SAITO, Kiyosu-shi (JP); Koji Okuno, Kiyosu-shi (JP); Yasuhisa Ushida, Kiyosu-shi (JP)

(73) Assignee: TOYODA GOSEI CO., LTD., Kiyosu-shi (JP)

(21) Appl. No.: 13/074,714

(22) Filed: Mar. 29, 2011

(30) Foreign Application Priority Data
Mar. 30, 2010 (JP) 2010-079191

(51) Int. Cl. H01L 33/22

(52) U.S. Cl. 438/29; 257/E33.074

(57) ABSTRACT

The present invention provides a method for producing a Group III nitride semiconductor light-emitting device whose main surface is a plane that provides an internal electric field of zero, and which exhibits improved light extraction performance. In the production method, one surface of an a-plane sapphire substrate is subjected to dry etching, to thereby form an embossment pattern having a plurality of mesas which are arranged in a honeycomb-dot pattern as viewed from above; and an n-type layer, a light-emitting layer, and a p-type layer, each of which is formed of a Group III nitride semiconductor layer having an m-plane main surface, are sequentially stacked on the surface of the sapphire substrate on which the mesas are formed. Subsequently, a p-electrode is formed on the p-type layer, and the p-electrode is bonded to a support substrate via a metal layer. Next, the sapphire substrate is removed through the laser lift-off process. On the thus-exposed surface of the n-type layer is formed an embossment pattern having dents provided through transfer of the mesas of the embossment pattern of the sapphire substrate. Then, the emboss-patterned surface of the n-type layer is subjected to wet etching, to thereby form numerous etched pits.

### BACKGROUND OF THE INVENTION

1. Field of the Invention

The present invention relates to a method for producing a Group III nitride semiconductor light-emitting device whose main surface is a plane which provides an internal electric field intensity of 10% or less that of a Group III nitride semiconductor layer having a c-plane main surface, and more particularly to a method for producing a Group III nitride semiconductor light-emitting device exhibiting improved light extraction performance.

2. Background Art

Hitherto, Group III nitride semiconductor light-emitting devices are generally produced from a Group III nitride semiconductor layer having a c-plane main surface. In such light-emitting devices, an internal electric field is generated in semiconductor crystals due to piezopolarization, which may cause problems, including reduction of emission performance and deterioration of crystallinity. Thus, in recent years, attempts have been made to produce a Group III nitride semiconductor light-emitting device whose main surface is a plane which provides an internal electric field of zero (e.g., m-plane or a-plane). Such a Group III nitride semiconductor light-emitting device having an m-plane or a-plane main surface is particularly suitable for use in, for example, a backlight of a liquid crystal panel, since light emitted from the device is polarized in a specific direction.

For example, Japanese Patent Application Laid-Open (kokai) No. 2006-36561 or 2009-203151 discloses a method for producing a Group III nitride semiconductor layer whose main surface is a plane which provides an internal electric field of zero. Japanese Patent Application Laid-Open (kokai) No. 2006-36561 or 2009-203151 discloses that a Group III nitride semiconductor layer whose main surface is a specific plane (e.g., m-plane or a-plane) can be formed by growing GaN crystal on side surfaces of dents or mesas of an embossed sapphire substrate.

Meanwhile, Japanese Patent Application Laid-Open (kokai) No. 2007-36240 discloses a technique for improving the light extraction performance of a Group III nitride semiconductor light-emitting device. This technique is as follows. Firstly, an n-type layer, a light-emitting layer, a p-type layer, and a p-electrode, each of which is formed of a Group III nitride semiconductor layer, are sequentially stacked on an embossed sapphire substrate. Subsequently, the p-electrode is bonded to a support via a bonding layer, and then the sapphire substrate is removed through the laser lift-off process. In this case, the embossment pattern of the sapphire substrate is transferred onto the surface of the n-type layer exposed through removal of the sapphire substrate. Next, the surface of the n-type layer is wet-etched with a strong alkaline solution, to thereby form, on the surface, an embossment which is finer than the above-transferred embossment pattern. Thus, the embossment pattern and the fine embossment provided on the surface of the n-type layer realize improvement of light extraction performance. Conceivably, the Group III nitride semiconductor layer employed has a c-plane main surface, although Japanese Patent Application Laid-Open (kokai) No. 2007-36240 does not particularly disclose the crystal orientation of the semiconductor layer.

In Group III nitride semiconductor light-emitting devices whose main surfaces are a plane which provides an internal electric field of zero, improvement of light extraction performance is also required.

One conceivable approach to improve light extraction performance is to form an embossment on the surface of a Group III nitride semiconductor layer. However, a non-polar plane surface (e.g., m-plane or a-plane surface) of a Group III nitride semiconductor layer is not readily wet-etched, since such a surface exhibits resistance to a strong alkaline solution. In addition, formation of an embossment through dry etching is not desirable, since dry etching may cause damage to crystals.

### SUMMARY OF THE INVENTION

In view of the foregoing, an object of the present invention is to improve the light extraction performance of a Group III nitride semiconductor light-emitting device whose main surface is a plane which provides an internal electric field of zero.

In a first aspect of the present invention, there is provided a method for producing a Group III nitride semiconductor light-emitting device, the method comprising sequentially stacking an n-type layer, a light-emitting layer, and a p-type layer on a surface of a sapphire substrate on which an embossment pattern has been provided, each of the layers being formed of a Group III nitride semiconductor layer which is formed through growth of a Group III nitride semiconductor crystal on side surfaces of dents or mesas of the embossment pattern, and whose main surface is a plane which provides an internal electric field intensity of 10% or less that of a Group III nitride semiconductor layer having a c-plane main surface; forming a p-electrode on the p-type layer; bonding the p-electrode to a support substrate; removing the sapphire substrate through the laser lift-off process, to thereby expose an embossment pattern on the surface of the n-type layer on the side of the sapphire substrate, the embossment pattern being an inverted pattern of the embossment pattern of the sapphire substrate; and wet etching the surface of the n-type layer exposed through removal of the sapphire substrate, to thereby form an etched pit.

As used herein, “Group III nitride semiconductor” encompasses a semiconductor represented by the formula AlₓGa_{y}In_{z}N(x+y+z=1, 0≦x, y, z≦1); such a semiconductor in which a portion of Al, Ga, or In is substituted by another Group 13 element (i.e., B or Tl), or a portion of N is substituted by another Group 15 element (i.e., P, As, Sb, or Bi). Specific examples of the Group III nitride semiconductor include those containing at least Ga, such as GaN, InGaN, AlGaN, and AlGaInN. Generally, Si is used as an n-type impurity, and Mg is used as a p-type impurity.

An example of a plane expressed by the term “plane which provides an internal electric field intensity of 10% or less that of a Group III nitride semiconductor layer having a c-plane main surface” is a non-polar plane (e.g., m-plane or a-plane) which is inclined by 90° with respect to c-plane of a Group III nitride semiconductor layer, or a plane inclined by 5° or less therewith. Another example is a semi-polar plane (e.g., (11-22) plane) which is inclined by about 60° with respect to c-plane of the semiconductor layer, or a plane inclined by 5° or less therewith. The most preferred plane is a plane which provides an internal electric field of zero; i.e., a non-polar plane (e.g., m-plane or a-plane) which is inclined by 90° with respect to c-plane, or a semi-polar plane which is inclined by about 60° with respect to c-plane. As used herein, the bar line which is conventionally provided above a component of a Miller index is denoted by the symbol “-” provided immediately before the component. The present invention employs a Group III nitride semiconductor layer having an internal electric field intensity of 10% or less that of a Group III nitride semiconductor layer having a c-plane main surface. The reason for this is that when the internal electric field intensity falls within such a range, emission performance is substantially not reduced, and emission wavelength shift to a longer wavelength can be prevented.

The crystal orientation of a Group III nitride semiconductor layer formed on an embossed sapphire substrate is determined by both the crystal orientation of the main surface of the sapphire substrate and the crystal orientation of side surfaces of dents (or mesas) of the embossment. Therefore, a Group III nitride semiconductor layer whose main surface is a specific plane (in particular, a Group III nitride semiconductor layer whose main surface is a plane which provides an internal electric field of zero) can be grown on the sapphire substrate by selecting the crystal orientation of the main surface and the embossment pattern of the sapphire substrate employed. This is as described in detail in Japanese Patent Application Laid-Open (kokai) No. 2006-36561 or 2009-203151. For example, a Group III nitride semiconductor layer having an m-plane main surface can be formed on a sapphire substrate having an a-plane main surface and an embossment in which dents extending in an m-axis direction are arranged in a stripe pattern as viewed from above.

Wet etching may be carried out by use of a strong alkaline solution; for example, TMAH, KOH, or NaOH. An acid such as phosphoric acid may be employed as an etchant.

The embossment pattern may be any embossment pattern (e.g., a stripe pattern or a dot pattern), so long as the pattern realizes crystal growth of a Group III nitride semiconductor layer whose main surface is a plane which provides an internal electric field intensity of 10% or less that of a Group III nitride semiconductor layer having a c-plane main surface. However, the embossment pattern is preferably a dot pattern rather than a stripe pattern, from the viewpoint of further improvement of light extraction performance. This is because when a stripe pattern is employed, light propagated along the stripe may fail to be extracted, since the direction of the light cannot be changed.

The embossment pattern suitable for forming a Group III nitride semiconductor layer whose main surface is a plane which provides an internal electric field intensity of 10% or less that of a Group III nitride semiconductor layer having a c-plane main surface does not necessarily correspond to the embossment pattern suitable for improving light extraction performance. Therefore, when a translucent insulating film (e.g., SiO₂ film) having a specific pattern is formed on the embossed sapphire substrate to thereby provide a second embossment pattern, and the first embossment pattern formed on the sapphire substrate is employed in combination with the second embossment pattern provided by the insulating film, an embossment pattern more suitable for improving light extraction performance can be formed on the surface of the n-type layer exposed through removal of the sapphire substrate. For example, in the case where the embossment pattern of the sapphire substrate is a stripe pattern, when the insulating film provides a stripe embossment pattern in which the direction of the stripe is inclined by a certain angle with respect to that of the stripe of the sapphire substrate, an embossment pattern suitable for improving light extraction performance can be formed. When the depth of the embossment pattern formed on the surface of the n-type layer is increased by means of the second embossment pattern provided by the insulating film, since −c-plane surfaces of large area—which are readily wet-etched—can be exposed on sides of dents or mesas, a larger number of deeper etched pits can be formed, and light extraction performance can be further improved.

Preferably, neither the embossment pattern of the n-type layer nor etched pits are provided on a region of the n-type layer surface on which an n-electrode is to be formed, since this provision deteriorates light extraction performance, due to multiple reflection and attenuation of light at the interface between the n-electrode and the embossment of the n-type layer.

The support substrate may be formed of a substrate of, for example, Si, Ge, GaAs, Cu, or Cu—W. The p-electrode is bonded to the support substrate via a metal layer. The metal layer may be a eutectic metal layer (i.e., low-melting-point metal layer), such as an Au—Sn layer, an Au—Si layer, an Ag—Sn—Cu layer, or an Sn—Bi layer. The metal layer may be, for example, an Au layer, an Sn layer, or a Cu layer, although such a metal does not exhibit low melting point. A metal layer (e.g., Cu layer) may be formed directly on the p-electrode through, for example, plating or sputtering, and the metal layer may be employed as a support substrate.

A second aspect of the present invention is drawn to a specific embodiment of the method for producing a Group III nitride semiconductor light-emitting device according to the first aspect, wherein the embossment pattern of the sapphire substrate has a plurality of mesas which are arranged in a dot pattern as viewed from above.

A third aspect of the present invention is drawn to a specific embodiment of the method for producing a Group III nitride semiconductor light-emitting device according to the first or second aspect, wherein the plane which provides an internal electric field intensity of 10% or less that of a Group III nitride semiconductor layer having a c-plane main surface is a plane which is inclined by 5° or less with respect to m-plane, a-plane, or a plane inclined by 60° with respect to c-plane.

A fourth aspect of the present invention is drawn to a specific embodiment of the method for producing a Group III nitride semiconductor light-emitting device according to any of the first to third aspects, which comprises forming, on the surface of the sapphire substrate having the embossment pattern, an embossment pattern through patterning of a translucent insulating film before formation of the n-type layer.

The insulating film may be formed of, for example, SiO₂, Si₃N₄, or AlN.

According to the first aspect, an embossment pattern can be formed on the surface of the n-type layer of the Group III nitride semiconductor light-emitting device, whose main surface is a plane which provides an internal electric field intensity of 10% or less that of a Group III nitride semiconductor layer having a c-plane main surface, although, hitherto, such a device has encountered difficulty in forming an embossment pattern. The surface of the n-type layer exposed through removal of the sapphire substrate has many crystal defects, since the surface is formed at an initial stage of crystal growth. Therefore, numerous etched pits can be formed in the surface through wet etching. Light extraction performance can be improved by virtue of both the embossment pattern formed on the surface of the n-type layer and a micro embossment provided through formation of the etched pits.

According to the second aspect, since the embossment pattern of the sapphire substrate is formed of a plurality of mesas which are arranged in a dot pattern as viewed from above, light extraction performance can be further improved.

According to the third aspect, the plane which provides an internal electric field intensity of 10% or less that of a Group III nitride semiconductor layer having a c-plane main surface may be a plane which is inclined by 5° or less with respect to m-plane, a-plane, or a plane inclined by 60° with respect to c-plane.

According to the fourth aspect, an embossment pattern more suitable for improving light extraction performance can be formed on the surface of the n-type layer by employing the embossment pattern formed on the sapphire substrate in combination with the embossment pattern provided by the insulating film.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIG. 1 shows the configuration of a light-emitting device 1 according to Embodiment 1;

FIGS. 2A to 2F are sketches showing processes for producing the light-emitting device 1 according to Embodiment 1;

FIG. 3 shows the configuration of a light-emitting device 2 according to Embodiment 2; and

FIGS. 4A to 4F are sketches showing processes for producing the light-emitting device 2 according to Embodiment 2.

### DETAILED DESCRIPTION OF PREFERRED EMBODIMENTS

Specific embodiments of the present invention will next be described with reference to the drawings. However, the present invention is not limited to the embodiments.

Embodiment 1

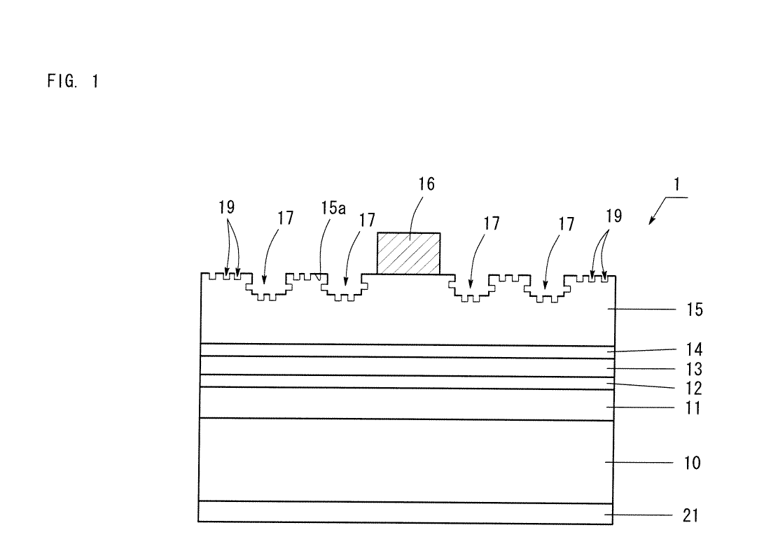

FIG. 1 shows the configuration of a light-emitting device 1 according to Embodiment 1. As shown in FIG. 1, the light-emitting device 1 includes a support substrate 10; a metal layer 11 formed on the support substrate 10; a p-electrode 12 bonded to the support substrate 10 via the metal layer 11; a p-type layer 13, a light-emitting layer 14, and an n-type layer 15, which are formed of a Group III nitride semiconductor and sequentially stacked on the p-electrode 12; and an n-electrode 16 formed on the n-type layer 15.

The support substrate 10 may be an electrically conductive substrate formed of, for example, Si, GaAs, Cu, or Cu—W. A bottom electrode 21 is formed on the bottom surface of the support substrate 10 (i.e., the surface on the side opposite the side of the p-electrode 12), so that electrical conduction is achieved in a direction perpendicular to the main surface of the light-emitting device 1. The metal layer 11 may be a low-melting-point metal layer; i.e., a eutectic metal layer such as an Au—Sn layer, an Au—Si layer, an Ag—Sn—Cu layer, or an Sn—Bi layer. Alternatively, the metal layer 11 may be, for example, an Au layer, an Sn layer, or a Cu layer, although such a metal does not exhibit low melting point. Instead of bonding the p-electrode 12 to the support substrate 10 via the metal layer 11, a metal layer (e.g., Cu layer) may be formed directly on the p-electrode 12 through, for example, plating, sputtering, or vapor deposition, and the metal layer may be employed as the support substrate 10. The p-electrode 12 is formed of a metal exhibiting high optical reflectance and low contact resistance, such as Ag, Rh, Pt, Ru, or an alloy predominantly containing such a metal. Alternatively, the p-electrode 12 may be formed of, for example, Ni, an Ni alloy, or an Au alloy, or may be formed of a composite layer including a transparent electrode film (e.g., ITO film) and a high-reflectance metal film.

Each of the p-type layer 13, the light-emitting layer 14, and the n-type layer 15 is a Group III nitride semiconductor layer having an m-plane main surface. Each of the p-type layer 13, the light-emitting layer 14, and the re-type layer 15 may have any of conventionally known structures for light-emitting devices. For example, the p-type layer 13 is formed of a p-cladding layer and a p-contact layer; the light-emitting layer has an MQW structure; and the n-type layer is formed of an n-cladding layer and an n-contact layer.

An embossment pattern is formed on the surface 15a of the n-type layer 15 (i.e., the surface on the side opposite the side of the light-emitting layer 14). The embossment pattern has a plurality of dents 17 which are arranged in a honeycomb-dot pattern as viewed from above. Each dent 17 has a regular hexagonal hollow columnar shape, and two facing side surfaces of the six side surfaces of the dent are +c-plane and −c-plane surfaces. Numerous etched pits 19 are formed on the bottom surfaces and side surfaces of the dents 17, and on regions of the surface 15a of the n-type layer 15 on which the dents 17 are not formed. Light extraction performance is improved by virtue of the embossment pattern provided by the dents 17 and the numerous etched pits 19.

The n-electrode 16 is formed on a region of the surface 15a of the n-type layer 15 on which the dents 17 are not formed. No particular limitation is imposed on the material of the n-electrode 16, so long as it can be in low-resistance contact with the n-type layer 15. The material of the n-electrode 16 may be, for example, V/Ni or Ti/Al. The n-electrode 16 may have a structure formed only of a pad portion. Alternatively, the n-electrode 16 may be formed of a pad portion and an electrode having a wiring pattern which is connected to the pad (e.g., lattice pattern or radial pattern), so as to improve diffusion of current in directions parallel to the main surface of the device. A transparent electrode (e.g., ITO electrode) may be provided between the n-type layer 15 and the n-electrode 16 so that the transparent electrode improves diffusion of current in the aforementioned directions.

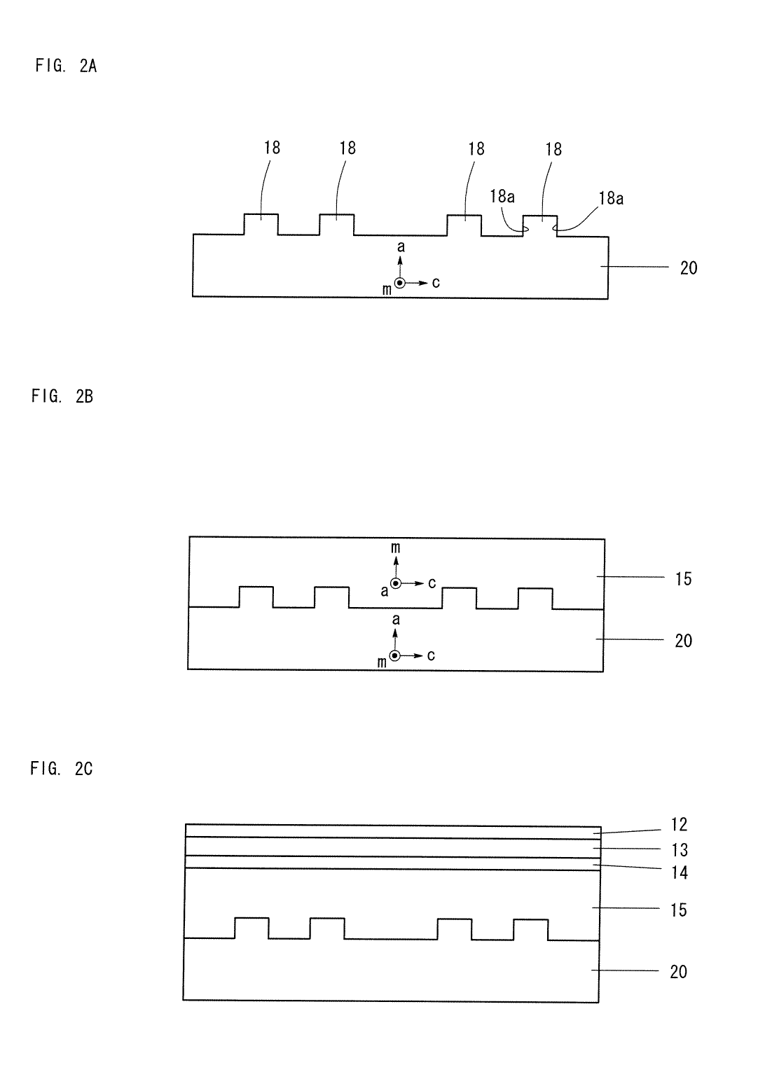

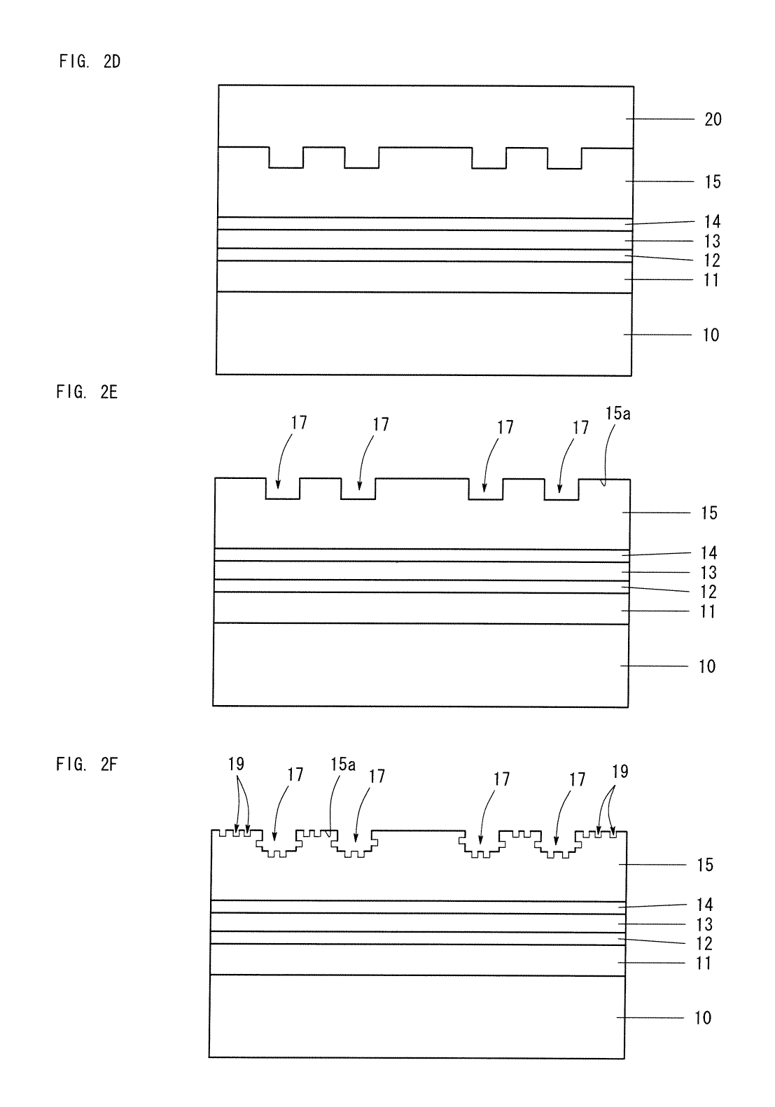

Next will be described processes for producing the light-emitting device 1 according to Embodiment 1 with reference to FIG. 2.

Firstly, one surface of an a-plane sapphire substrate 20 is subjected to dry etching, to thereby form an embossment pattern having a plurality of mesas 18 which are arranged in a honeycomb-dot pattern as viewed from above (FIG. 2A). Each mesa 18 has a regular hexagonal columnar shape, and two facing side surfaces 18a of the six side surfaces of the mesa are c-plane surfaces.

Subsequently, the sapphire substrate 20 is heated in a hydrogen atmosphere for thermal cleaning. This cleaning repairs etching damage caused by formation of the mesas 18, and also removes impurities or oxides from the surface of the sapphire substrate 20.

After cooling of the sapphire substrate 20 to 300 to 420° C., TMA (trimethylaluminum) is supplied, and the exposed surface of the sapphire substrate 20 is covered with Al, to thereby form an Al thin film. A gas mixture of hydrogen and nitrogen is employed as a carrier gas. Next, supply of TMA is stopped; the carrier gas and ammonia gas are supplied; and the sapphire substrate 20 is heated to 1,010° C. This process forms an AlN thin film (not illustrated) on the sapphire substrate 20. The thus-formed AlN thin film functions as a buffer layer, promotes crystal growth of a Group III nitride semiconductor on side surfaces 18a (i.e., c-plane surfaces) of the mesas 18, and suppresses crystal growth of the Group III nitride semiconductor on other surfaces (including non-c-plane side surfaces of the mesas 18, the top surfaces of the mesas 18, and surfaces parallel to the surface of the sapphire substrate 20 exposed through etching).

Subsequently, an n-type Group III nitride semiconductor crystal is grown through MOCVD. At an initial stage of crystal growth, the Group III nitride semiconductor is grown on the side surfaces 18a (i.e., c-plane surfaces) of the mesas 18 via the AlN thin film, and growth thereof is suppressed on the other surfaces. In this case, the n-type Group III nitride semiconductor is grown so that the c-axis direction of the semiconductor is parallel to the c-axis direction of the sapphire substrate 20, and the m-axis direction of the semiconductor is parallel to the direction perpendicular to the main surface of the sapphire substrate 20. As crystal growth proceeds, the entire top surface of the sapphire substrate 20 is gradually covered with the n-type Group III nitride semiconductor grown on the side surfaces 18a of the mesas 18, and eventually, the flat n-type layer 15 of the n-type Group III nitride semiconductor having an m-plane main surface is formed on the sapphire substrate 20 (FIG. 2B).

Preferably, one of the two side surfaces 18a (i.e., c-plane surfaces) of each mesa 18 is covered with, for example, an SiO₂ mask, and then crystal growth of the Group III nitride semiconductor is carried out. This is because the thus-grown Group III nitride semiconductor has uniform polarity, e.g., the growth direction is +c-axis direction, and the n-type layer 15 exhibits further improved crystallinity.

Next, the light-emitting layer 14 and the p-type layer 13 are sequentially stacked on the n-type layer 15 through MOCVD, and the p-electrode 12 is formed on the p-type layer 13 through sputtering (FIG. 2C). Each of the light-emitting layer 14 and the p-type layer 13 is a Group III nitride semiconductor layer having an m-plane main surface, since the layers 14 and 13 are grown so as to achieve lattice matching with the n-type layer 15.

The carrier gas, raw material gases, and dopant gases employed for formation of the p-type layer 13, the light-emitting layer 14, and the n-type layer 15 are as follows: carrier gas: a gas mixture of hydrogen and nitrogen; raw material gases: ammonia as a nitrogen source, TMG (trimethylgallium) as a Ga source, TMI (trimethylindium) as an In source, and TMA (trimethylaluminum) as an Al source; and dopant gases: silane as an n-type dopant gas and Cp₂Mg (biscyclopentadienylmagnesium) as a p-type dopant gas.

Subsequently, the support substrate 10 is provided, and the support substrate 10 is bonded to the p-electrode 12 via the metal layer 11 (FIG. 2D). A non-illustrated diffusion-preventing layer may be formed in advance between the p-electrode 12 and the metal layer 11, so as to prevent diffusion of the metal of the metal layer 11 toward the p-electrode 12.

Then, a laser beam is applied onto the side of the sapphire substrate 20, to thereby separate/remove the sapphire substrate 20 through the laser lift-off process (FIG. 2E), and the surface 15a of the n-type layer 15 exposed through removal of the sapphire substrate 20 is washed with hydrochloric acid. Since the mesas 18 are formed on the surface of the sapphire substrate 20, dents 17 corresponding to the mesas 18 are formed in the surface 15a of the n-type layer 15. Thus, the embossment pattern formed by the dents 17, which is an inverted pattern of the embossment pattern formed by the mesas 18 of the sapphire substrate 20, is provided on the surface 15a of the n-type layer 15.

Next, the surface 15a of the n-type layer 15 is subjected to wet etching by use of an aqueous TMAH solution. The surface 15a of the n-type layer 15 has many crystal defects, since the surface 15a is on the side of the interface between the n-type layer 15 and the sapphire substrate 20, and is formed at an initial stage of crystal growth. Therefore, numerous etched pits 19 are formed in the surface 15a of the n-type layer 15 through this wet etching process (FIG. 2F). The non-illustrated AlN thin film formed between the sapphire substrate 20 and the n-type layer is removed through this wet etching process.

Preferably, neither the embossment pattern formed by the dents 17 nor the etched pits 19 are provided on a region of the surface 15a of the n-type layer 15 on which the n-electrode 16 is to be formed through the subsequent process; i.e., the electrode formation region remains flat. This is because when the n-electrode 16 is formed on a region having the embossment pattern, light extraction performance is deteriorated, due to multiple reflection and attenuation of light at the interface between the n-electrode 16 and the re-type layer 15 having the embossment pattern or the etched pits.

Subsequently, the n-electrode 16 is formed on the surface 15a of the n-type layer 15 through the lift-off process, and the bottom electrode 21 is formed on the surface of the support substrate 10 on the side opposite the side of the metal layer 11. The resultant wafer is separated into chips through, for example, laser dicing, to thereby produce the light-emitting device 1 according to Embodiment 1 shown in FIG. 1.

According to the above-described production method for the light-emitting device 1 of Embodiment 1, since an embossment pattern can be formed on the surface of the n-type layer 15 having an m-plane main surface, and also a micro embossment can be provided through formation of the etched pits 19, light extraction performance can be improved.

The embossment pattern formed on the surface 20a of the sapphire substrate 20 is not limited to the aforementioned dot pattern formed through arrangement of mesas. For example, even when a plurality of mesas or dents are formed on the sapphire substrate 20 having an a-plane main surface so that the mesas or the dents are arranged in a stripe pattern as viewed from above and the direction of the stripe is in an m-axis direction, a Group III nitride semiconductor layer having an m-plane main surface can be formed on the sapphire substrate 20 as in the case of Embodiment 1. However, when such a stripe embossment pattern is employed, light propagated along the stripe may fail to be extracted to the outside by changing the direction of the light, and thus light extraction performance is lowered, which is not preferred. Therefore, after formation of the stripe embossment pattern, a translucent insulating film (e.g., SiO₂ film) having an embossment pattern may be provided on the sapphire substrate 20. When the embossment pattern formed on the sapphire substrate 20 is employed in combination with the embossment pattern provided by the insulating film, an embossment pattern which realizes more effective light extraction can be formed on the surface 15a of the n-type layer 15. Needless to say, as also in the case of Embodiment 1 (i.e., in the case of the dot embossment pattern formed on the surface of the sapphire substrate), when the embossment pattern is employed in combination with the embossment pattern provided by the insulating film, an embossment pattern which realizes more effective light extraction can be formed on the surface 15a of the n-type layer 15.

The emboss-patterned insulating film formed on the sapphire substrate is removed by use of, for example, buffered hydrofluoric acid after removal of the sapphire substrate through the laser lift-off process.

When the embossment pattern of the substrate is employed in combination with the embossment pattern provided by the insulating film, the depth of the dents 17 formed in the surface 15a of the n-type layer 15 can be increased, whereby the side surfaces of the dents 17 (i.e., −c-plane surfaces) can be exposed over a larger area. Since the -−c-plane surfaces are readily wet-etched, a large number of deep etched pits can be formed, and light extraction performance can be further improved.

A quasi-periodic embossment pattern (e.g., Penrose tile pattern) may be formed on the surface 15a of the n-type layer 15 by employing only the embossment pattern on the surface of the sapphire substrate 20, or combination of the embossment pattern on the surface of the sapphire substrate 20 and the embossment pattern provided by the insulating film. When such a quasi-periodic embossment pattern is provided, dents (or mesas) are not periodically arranged in any direction parallel to the main surface of the device, and thus light extraction performance can be further improved.

### Embodiment 2

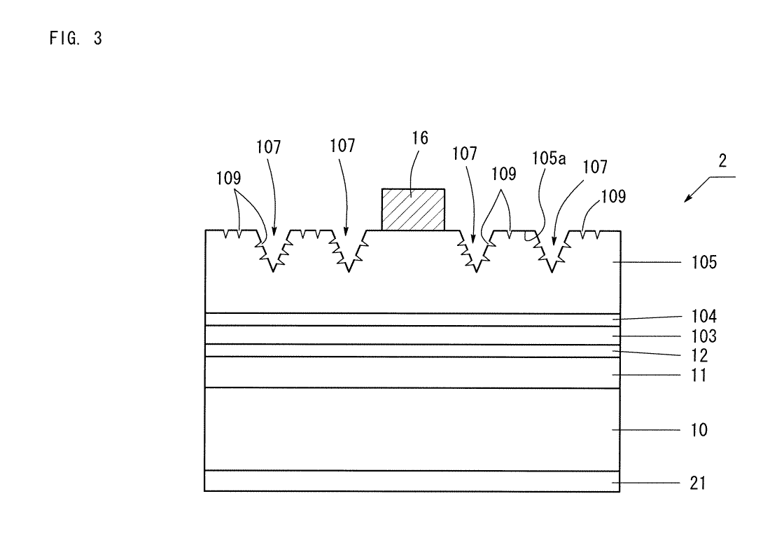

FIG. 3 shows the configuration of a light-emitting device 2 according to Embodiment 2. As shown in FIG. 3, the light-emitting device 2 includes a support substrate 10; a metal layer 11 formed on the support substrate 10; a p-electrode 12 bonded to the support substrate 10 via the metal layer 11; a p-type layer 103, a light-emitting layer 104, and an n-type layer 105, which are formed of a Group III nitride semiconductor and sequentially stacked on the p-electrode 12; and an n-electrode 16 formed on the n-type layer 105. The light-emitting device 2 has the same configuration as the light-emitting device 1 according to Embodiment 1, except for the p-type layer 103, the light-emitting layer 104, and the n-type layer 105.

Each of the p-type layer 103, the light-emitting layer 104, and the n-type layer 105 is formed of a Group III nitride semiconductor layer having a (11-22)-plane main surface. The (11-22)-plane surface is inclined by about 60° with respect to c-plane, and provides an internal electric field of almost zero (i.e., an internal electric field of −10 to 10% that of a Group III nitride semiconductor layer having a c-plane main surface). Similar to the cases of the p-type layer 13, the light-emitting layer 14, and the n-type layer 15 of the light-emitting device 1 according to Embodiment 1, each of the p-type layer 103, the light-emitting layer 104, and the n-type layer 105 may have any of conventionally known structures for light-emitting devices.

An embossment pattern is formed on the surface 105a of the n-type layer 105 (i.e., the surface on the side opposite the side of the light-emitting layer 104). The embossment pattern has a plurality of dents 107 which are arranged in a honeycomb-dot pattern as viewed from above. Each dent 107 has a hexagonal hollow pyramidal shape, and at least one of the six inclined side surfaces of the dent is a +c-plane surface. Numerous etched pits 109 are formed on the side surfaces of the dents 107, and on regions of the surface 105a of the n-type layer 105 on which the dents 107 are not formed. Light extraction performance is improved by virtue of the embossment pattern provided by the dents 107 and the numerous etched pits 109.

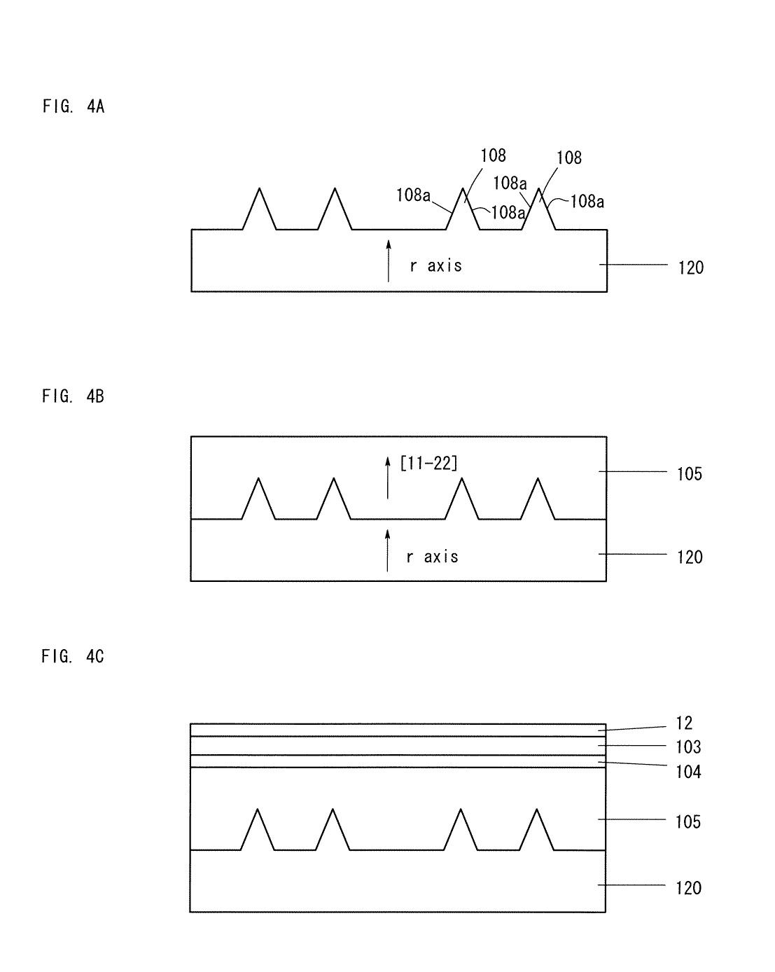

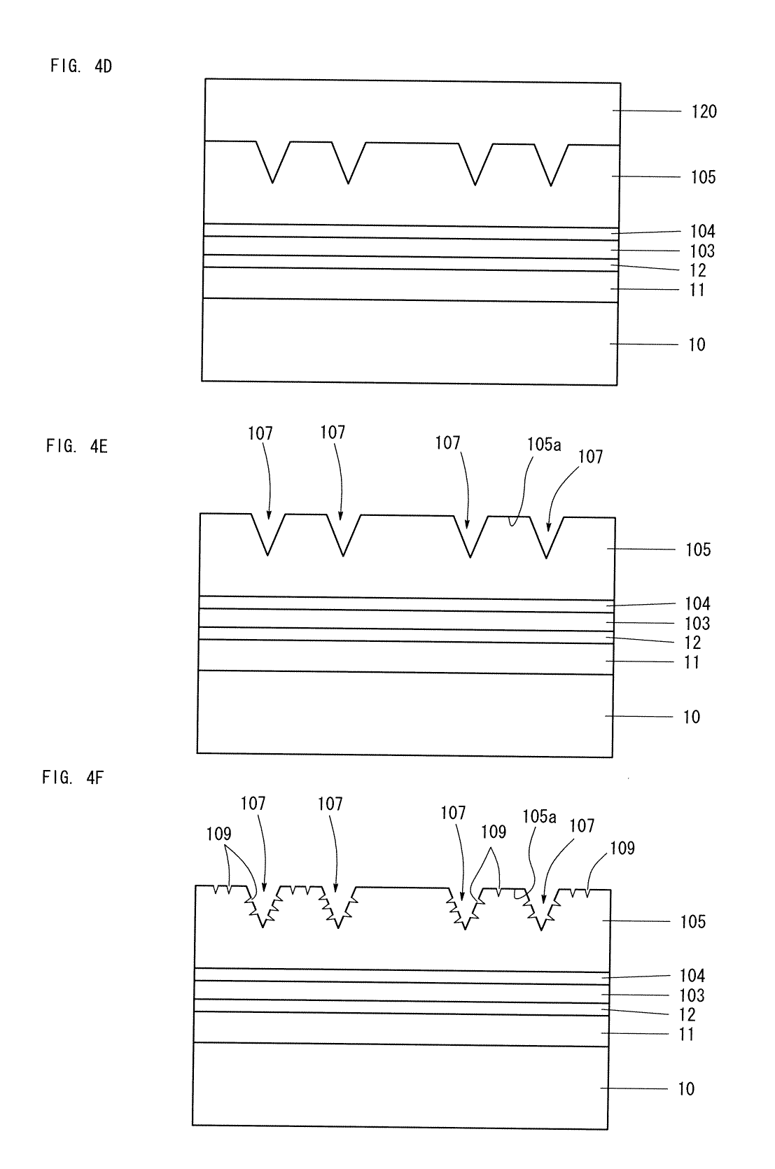

Next will be described processes for producing the light-emitting device 2 according to Embodiment 2 with reference to FIG. 4.

Firstly, one surface of a sapphire substrate 120 having an r-plane ((1-102)-plane) main surface is subjected to dry etching, to thereby form an embossment pattern having a plurality of mesas 108 which are arranged in a honeycomb-dot pattern as viewed from above (FIG. 4A). Each mesa 108 has a hexagonal pyramidal shape, and at least one of the six inclined side surfaces 108a of the mesa is a c-plane surface.

Subsequently, the sapphire substrate 120 is heated in a hydrogen atmosphere for thermal cleaning. This cleaning repairs etching damage caused by formation of the mesas 108, and also removes impurities or oxides from the surface of the sapphire substrate 120.

After cooling of the sapphire substrate 120 to 300 to 420° C., TMA (trimethylaluminum) is supplied, and the exposed surface of the sapphire substrate 120 is covered with Al, to thereby form an Al thin film. A gas mixture of hydrogen and nitrogen is employed as a carrier gas. Next, supply of TMA is stopped; the carrier gas and ammonia gas are supplied; and the sapphire substrate 120 is heated to 1,010° C. This process forms an AlN thin film (not illustrated) on the sapphire substrate 120. The thus-formed AlN thin film functions as a buffer layer, promotes crystal growth of a Group III nitride semiconductor on the c-plane side surfaces of the mesas 108, and suppresses crystal growth of the Group III nitride semiconductor on other surfaces (including non-c-plane side surfaces of the mesas 108, and surfaces parallel to the surface of the sapphire substrate 120 exposed through etching).

Subsequently, an n-type Group III nitride semiconductor crystal is grown through MOCVD. At an initial stage of crystal growth, the Group III nitride semiconductor is grown on the c-plane side surfaces of the mesas 108 via the AlN thin film, and growth thereof is suppressed on the other surfaces. In this case, the Group III nitride semiconductor is grown so that the c-axis direction of the semiconductor is parallel to the c-axis direction of the sapphire substrate 120, and the m-axis direction of the semiconductor is parallel to the a-axis direction of the sapphire substrate 120. As crystal growth proceeds, the entire top surface of the sapphire substrate 120 is gradually covered with the n-type Group III nitride semiconductor grown on the c-plane side surfaces of the mesas 108, and eventually, the flat n-type layer 105 of the n-type Group III nitride semiconductor is formed on the sapphire substrate 120 (FIG. 4B). In this case, the c-axis direction of the n-type layer 105 corresponds to the c-axis direction of the sapphire substrate 120, and the m-axis direction of the n-type layer 105 corresponds to the a-axis direction of the sapphire substrate 120. Therefore, the n-type layer 105, which is formed on the sapphire substrate 120 having an r-plane ((1-102)-plane) main surface, has a (11-22)-plane main surface.

Next, the light-emitting layer 104 and the p-type layer 103 are sequentially stacked on the n-type layer 105 through MOCVD, and the p-electrode 12 is formed on the p-type layer 103 through sputtering (FIG. 4C). Each of the light-emitting layer 104 and the p-type layer 103 is a Group III nitride semiconductor layer having a (11-22)-plane main surface, since the layers 104 and 103 are grown so as to achieve lattice matching with the n-type layer 105.

Subsequently, the support substrate 10 is provided, and the support substrate 10 is bonded to the p-electrode 12 via the metal layer 11 (FIG. 4D).

Then, a laser beam is applied onto the side of the sapphire substrate 120, to thereby separate/remove the sapphire substrate 120 through the laser lift-off process (FIG. 4E), and the surface 105a of the n-type layer 105 exposed through removal of the sapphire substrate 120 is washed with hydrochloric acid. Since the mesas 108 are formed on the surface of the sapphire substrate 120, dents 107 corresponding to the mesas 108 are formed in the surface 105a of the n-type layer 105. Thus, the embossment pattern formed by the dents 107, which is an inverted pattern of the embossment pattern formed by the mesas 108 of the sapphire substrate 120, is provided on the surface 105a of the n-type layer 105.

Next, the surface 105a of the n-type layer 105 is subjected to wet etching by use of an aqueous TMAH solution. The surface 105a of the n-type layer 105 has many crystal defects, since the surface 105a is on the side of the interface between the n-type layer 105 and the sapphire substrate 120, and is formed at an initial stage of crystal growth. Therefore, numerous etched pits 109 are formed in the surface 105a of the n-type layer 105 through this wet etching process (FIG. 4F). The non-illustrated AlN thin film formed between the sapphire substrate 120 and the n-type layer is removed through this wet etching process.

Subsequently, the n-electrode 16 is formed on the surface 105a of the n-type layer 105 through the lift-off process, and the bottom electrode 21 is formed on the surface of the support substrate 10 on the side opposite the side of the metal layer 11. The resultant wafer is separated into chips through, for example, laser dicing, to thereby produce the light-emitting device 2 according to Embodiment 2 shown in FIG. 3.

According to the above-described production method for the light-emitting device 2 of Embodiment 2, since an embossment pattern can be formed on the surface of the n-type layer 105 having a (11-22)-plane main surface, and also a micro embossment can be provided through formation of the etched pits 109, light extraction performance can be improved.

Embodiment 1 is directed to the method for producing the Group III nitride semiconductor light-emitting device having an m-plane main surface by using, as a growth substrate, an a-plane sapphire substrate having thereon an embossment pattern. Embodiment 2 is directed to the method for producing the Group III nitride semiconductor light-emitting device having a (11-22)-plane main surface by using, as a growth substrate, an r-plane sapphire substrate having thereon an embossment pattern. However, the present invention is not limited to these production methods. The present invention may also be applied to a method for producing, by using an emboss-patterned sapphire substrate as a growth substrate, another Group III nitride semiconductor light-emitting device whose main surface is a plane which provides an internal electric field of zero; i.e., a plane which is inclined by 90° with respect to c-plane (e.g., a-plane), or a plane which is inclined by about 60° with respect to c-plane. The main surface of such a light-emitting device may be a plane which is inclined by 5° or less with respect to a plane which provides an internal electric field of zero (e.g., m-plane, a-plane, or (11-22) plane). The main surface of such a light-emitting device is not necessarily a plane which provides an internal electric field of zero, and may be a plane which provides an internal electric field intensity of 10% or less that of a Group III nitride semiconductor layer having a c-plane main surface.

The Group III nitride semiconductor light-emitting device of the present invention can be employed in, for example, an illumination apparatus, a display apparatus, or a backlight.

What is claimed is:

1. A method for producing a Group III nitride semiconductor light-emitting device, the method comprising:
sequentially stacking an n-type layer, a light-emitting layer, and a p-type layer on a surface of a sapphire substrate on which an embossment pattern has been provided, each of the layers being formed of a Group III nitride semiconductor layer which is formed through growth of a Group III nitride semiconductor crystal on side surfaces of dents or mesas of the embossment pattern, and whose main surface is a plane which provides an internal electric field intensity of 10% or less that of a Group III nitride semiconductor layer having a c-plane main surface;
forming a p-electrode on the p-type layer;
bonding the p-electrode to a support substrate;
removing the sapphire substrate through the laser lift-off process, to thereby expose an embossment pattern on the surface of the n-type layer on the side of the sapphire substrate, the embossment pattern being an inverted pattern of the embossment pattern of the sapphire substrate; and
wet etching the surface of the n-type layer exposed through removal of the sapphire substrate, to thereby form an etched pit.

2. A method for producing a Group III nitride semiconductor light-emitting device according to claim 1, wherein the embossment pattern of the sapphire substrate has a plurality of mesas which are arranged in a dot pattern as viewed from above.

3. A method for producing a Group III nitride semiconductor light-emitting device according to claim 1, wherein the plane which provides an internal electric field intensity of 10% or less that of a Group III nitride semiconductor layer having a c-plane main surface is a plane which is inclined by 5° or less with respect to m-plane, a-plane, or a plane inclined by 60° with respect to c-plane.

4. A method for producing a Group III nitride semiconductor light-emitting device according to claim 2, wherein the plane which provides an internal electric field intensity of 10% or less that of a Group III nitride semiconductor layer having a c-plane main surface is a plane which is inclined by 5° or less with respect to m-plane, a-plane, or a plane inclined by 60° with respect to c-plane.

5. A method for producing a Group III nitride semiconductor light-emitting device according to claim 1, which comprises forming, on the surface of the sapphire substrate having the embossment pattern, an embossment pattern through patterning of a translucent insulating film before formation of the n-type layer.

6. A method for producing a Group III nitride semiconductor light-emitting device according to claim 2, which comprises forming, on the surface of the sapphire substrate having the embossment pattern, an embossment pattern through patterning of a translucent insulating film before formation of the n-type layer.

7. A method for producing a Group III nitride semiconductor light-emitting device according to claim 3, which comprises forming, on the surface of the sapphire substrate having the embossment pattern, an embossment pattern through patterning of a translucent insulating film before formation of the n-type layer.

8. A method for producing a Group III nitride semiconductor light-emitting device according to claim 4, which comprises forming, on the surface of the sapphire substrate having the embossment pattern, an embossment pattern through patterning of a translucent insulating film before formation of the n-type layer.
